(19) United States
(12) Patent Application Publication
(10) Pub. No.: US 2015/0318286 A1
(43) Pub. Date: Nov. 5, 2015

(54) SEMICONDUCTOR DEVICE AND METHOD OF MANUFACTURING THE SAME

(71) Applicants: Nan WU, Chuo-ku, Tokyo (JP); PS5 LUXCO S.A.R.L., Luxembourg (LU)

(72) Inventor: Noriyasu Ikeda, Tokyo (JP)

(21) Appl. No.: 14/441,911

(22) PCT Filed: Nov. 11, 2013
(86) PCT No.: PCT/JP2013/080389

§ 371 Date: May 11, 2015

(30) Foreign Application Priority Data
Nov. 15, 2012 (JP) 2012-251378

(51) Int. Cl. H01L 27/108; H01L 21/02; H01L 21/311

(52) U.S. Cl. CPC H01L 27/10885; H01L 27/10873; H01L 27/10894; H01L 27/10805; H01L 21/31111; H01L 21/02282; H01L 21/02271; H01L 21/02164; H01L 21/02208

(57) ABSTRACT

This semiconductor device comprises: a bit line that is arranged in a memory cell region on a semiconductor substrate; and a gate electrode of a transistor for a peripheral circuit, which is arranged in a peripheral circuit region on the semiconductor substrate. The lateral surface of the gate electrode is provided with a plurality of side wall insulating films, while the lateral surface of the bit line is provided with a single side wall insulating film.

### TECHNICAL FIELD

The present invention relates to a semiconductor device and a method of manufacturing the same.

### BACKGROUND ART

A semiconductor device forming part of a DRAM (Dynamic Random Access Memory) comprises a memory cell region and a peripheral circuit region for driving the memory cells. A memory cell is formed by a single switching transistor and a single capacitive element. A memory cell region is formed by arranging a plurality of memory cells in matrix fashion. A plurality of word lines for driving the plurality of switching transistors and a plurality of bit lines for reading the information in the plurality of capacitive elements or writing information thereto are arranged in the entire memory cell region. The bit lines extend in a direction orthogonal to the direction of extension of the word lines and are connected to sensing amplifiers while extending to the peripheral circuit region. In the peripheral circuit region, apart from the sensing amplifiers, various peripheral circuits are arranged, and a plurality of peripheral circuit transistors (hereinbelow referred to as peripheral Tr's) are connected.

In recent years, with increasing miniaturization of DRAMs, buried word line-type DRAMs, constructed by burying word lines forming memory cells in a semiconductor substrate, have come to be employed. As a result, a construction is produced in which bit lines are arranged on the semiconductor substrate of the memory cell region. It therefore becomes possible to form the bit lines and gate electrodes (hereinbelow referred to as peripheral gates) of the peripheral Tr's that are positioned on the semiconductor substrate in the peripheral circuit region in the same step.

Patent Reference 1 discloses a method of manufacturing the bit lines of the memory cells and the peripheral gates of the peripheral circuits in the same step in a buried word line-type DRAM.

### PATENT REFERENCES

Patent Reference 1: Laid-open Japanese Patent Application Number 2012-19035

### OUTLINE OF THE INVENTION

### Problem that the Invention is Intended to Solve

In the method of manufacture set out in Patent Reference 1, sidewall insulating films covering the lateral surfaces of the peripheral gates are formed by a single-layer film and sidewall insulating films covering the lateral surfaces of the bit lines are also formed by a single-layer film. Also, the source-drain diffusion layer forming part of the peripheral Tr's is formed by a single impurity diffusion layer.

However, as miniaturization of DRAMs has progressed, in order to achieve high dielectric strength of the peripheral Tr's, source-drain diffusion layers have come to be employed having an LDD (Lightly Doped Drain) diffusion layer as the electric field buffering layer. In this case, since impurity must be introduced at two locations, namely, directly below the lateral surface of the peripheral gate and a position remote from the lateral surface of the peripheral gate, using double ion implantation, it becomes necessary to provide a plurality of sidewall insulating films at the lateral surface of the peripheral gate.

Also, SOD (Spin-On Dielectric) films, which are formed by a spin-coating method, have come to be employed in order to effectively bury surface irregularities that are produced on the semiconductor substrate surface by formation of the peripheral gates and bit lines. When an SOD film is employed, it is necessary to cover the surface where the SOD film is to be formed with a silicon nitride film. This is because if the surface where the SOD film is to be formed is not covered with a silicon nitride film, there is a drawback in that there is insufficient reformation of the subsequent SOD film, so that it no longer functions as an interlayer insulating film.

For the reason described above, the result is that a situation is produced in which a plurality of sidewall insulating films are also formed on the lateral surface of the bit lines. The spacing of the plurality of bit lines formed in the memory cell region is already narrow, but the formation of a plurality of sidewalls makes it even narrower. As a result, the problem arises that it becomes impossible to form the contact plugs for the capacitive elements between adjacent bit lines. Even if contact plugs can be formed, the contact area is reduced, so the contact resistance is raised, leading to the problem that operation of the DRAM is slowed down.

### Means for Solving the Problem

A semiconductor device according to one mode of the present invention comprises a memory cell region and a peripheral circuit region on a semiconductor substrate. The semiconductor device also includes bit lines arranged on the semiconductor substrate in the memory cell region and gate electrodes of transistors for peripheral circuits arranged on the semiconductor substrate in the peripheral circuit region. A plurality of sidewall insulating films are provided on the lateral surfaces of the gate electrodes and a single-layer sidewall insulating film is arranged on the lateral surfaces of the bit lines.

In another mode of the present invention, a method of manufacturing a DRAM semiconductor device is provided, said method including a step of forming a plurality of bit lines in a memory cell region on a semiconductor substrate and simultaneously forming gate electrodes of transistors for peripheral circuits in a peripheral circuit region. This method of manufacture includes: a step of forming, by etching back, a first liner film using a first insulating film only in a portion contacting the lateral surfaces of the bit lines and the lateral surfaces of the gate electrodes, after deposition of the first insulating film so as to cover the bit lines and the gate electrodes; and a step of forming, by etching back, a spacing film using a second insulating film only in a portion contacting the lateral surfaces of the bit lines and the gate electrodes covered by the first liner film, after deposition, to a prescribed thickness, of the second insulating film, which is made of a different material from the first insulating film, in a region including the surfaces of the bit lines and the gate electrodes and the lateral surfaces covered by the first liner film. With this method of manufacture, the interval between the plurality of bit lines is set so that, when the spacing film is formed to the prescribed thickness, the space between adjacent bit lines is buried by the first liner film and the spacing film formed thereon. After the step of forming the spacing film, this method of manufacture further includes a step of depositing a third insulating film made of the same material as the first insulating film in a region including the surfaces of the bit lines and the gate electrodes and the lateral surfaces covered by the first liner film and the spacing film, and then forming, by etching back, a second liner film using the third insulating film, only in a portion contacting the lateral surfaces of the gate electrodes covered by the spacing film and the first liner film.

### Beneficial Effect of the Invention

With a semiconductor device according to the present invention, even if a plurality of sidewall insulating films are arranged on the lateral surface of the gate electrodes of the transistors for the peripheral circuits, the sidewall insulating film that is arranged on the lateral surface of the bit lines of the memory cell region is formed by a single layer, and therefore slowing down of the operation of the DRAM can be avoided, by reducing the contact resistance of the contact plugs for the capacitive elements that are formed between adjacent bit lines.

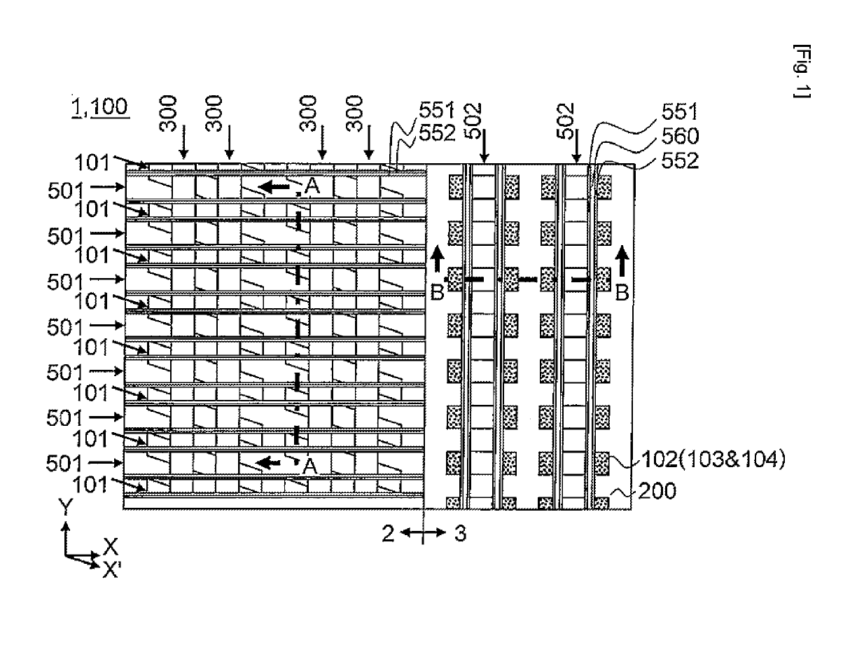

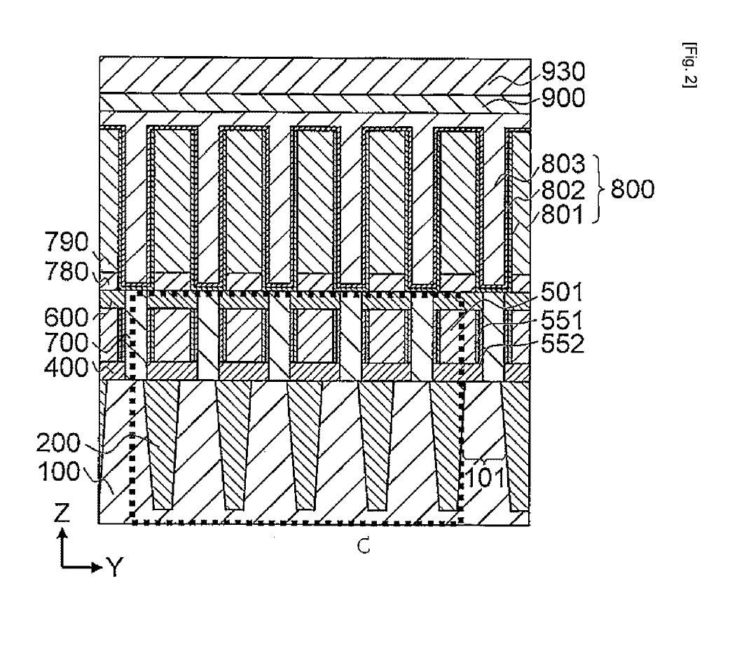

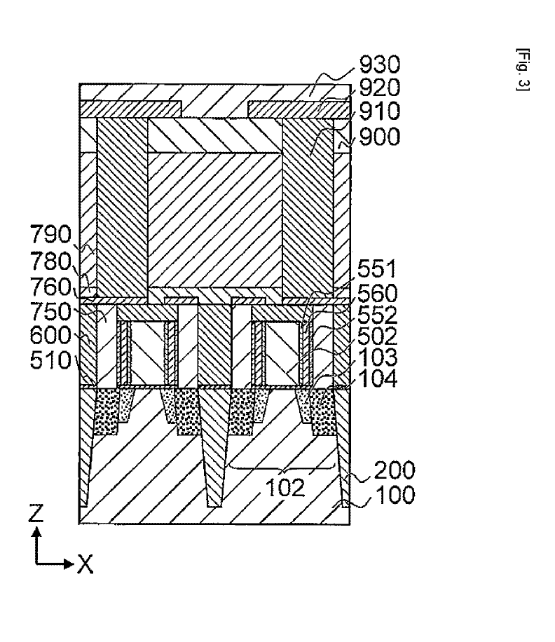

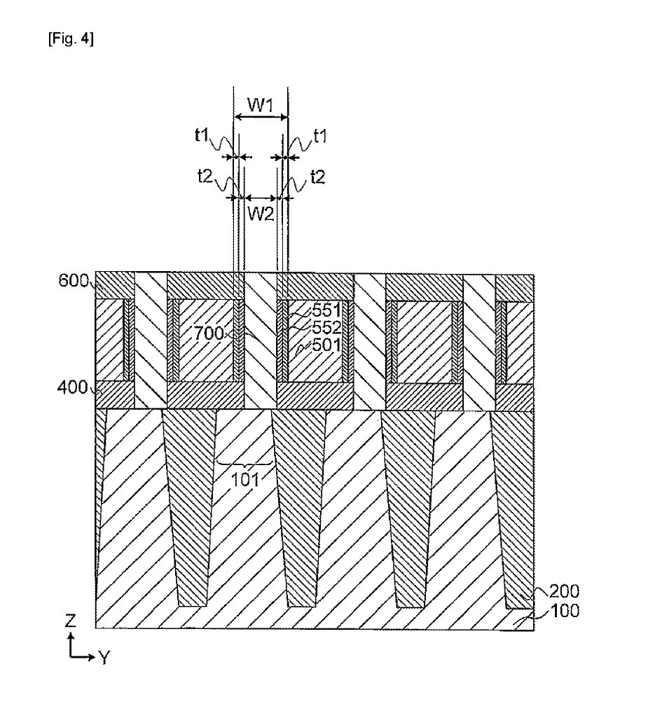

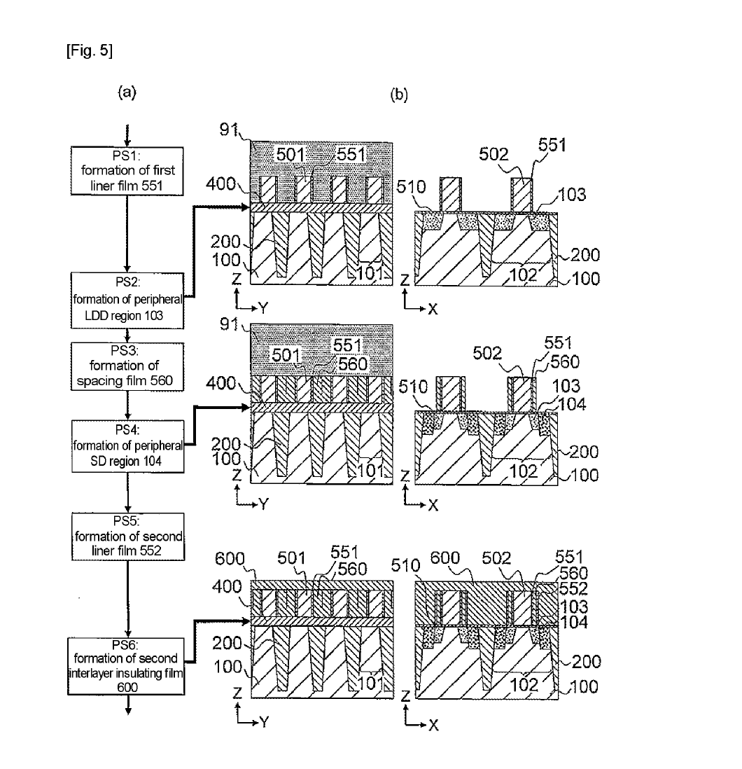

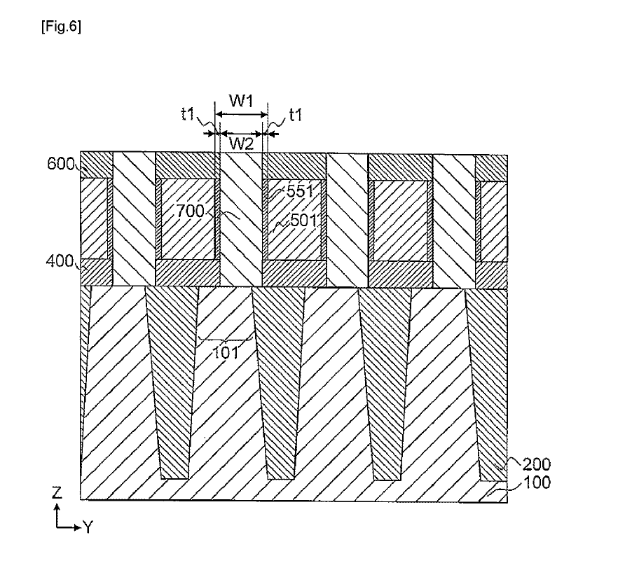

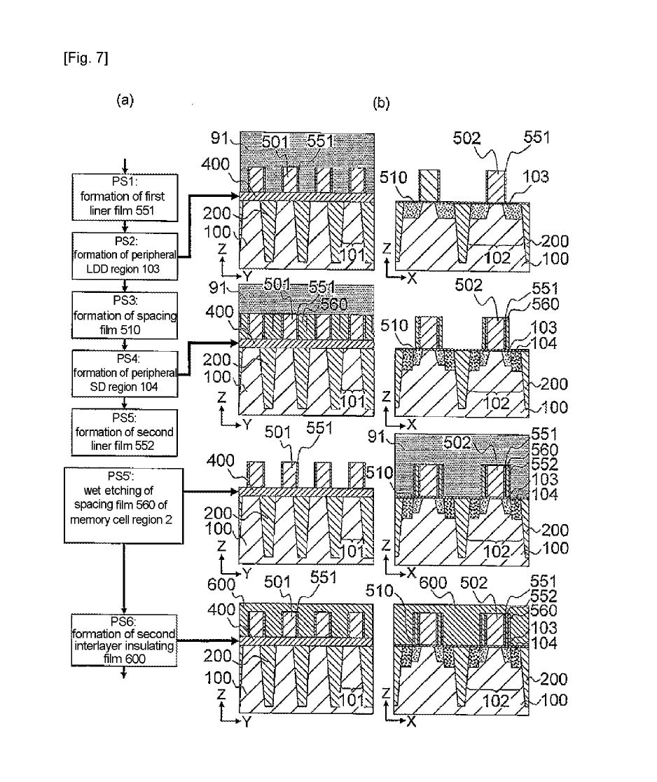

### BRIEF DESCRIPTION OF THE DRAWINGS

[FIG. 1] is a plan view showing the arrangement of the major portions as far as the peripheral gates and the bit lines of a DRAM semiconductor device used for a preliminary study by the present inventor.

[FIG. 2] is a cross-sectional view along the line A-A of FIG. 1.

[FIG. 3] is a cross-sectional view along the line B-B of FIG. 1.

[FIG. 4] is an enlargement within the box C defined by the broken line of FIG. 2.

[FIG. 5] is a cross-sectional view showing the outline of a method of manufacturing a semiconductor device according to a first embodiment of the present invention in step order, and showing the changes in the cross-sectional shape of major portions of a semiconductor device in specified steps.

[FIG. 6] is a cross-sectional view showing major portions of a semiconductor device according to the first embodiment of the present invention, corresponding to FIG. 4.

[FIG. 7] is a cross-sectional view showing the outline of a method of manufacturing a semiconductor device according to a second embodiment of the present invention in step order, and showing the changes in the cross-sectional shape of major portions of a semiconductor device in specified steps.

### MODE FOR IMPLEMENTING THE INVENTION

Before describing an embodiment of the present invention, a description will be given using FIG. 1 to FIG. 3 concerning the details of the preliminary study carried out by the present inventor.

FIG. 1 is a plan view showing the arrangement of the major portions as far as bit lines 501 and peripheral gates 502 of a DRAM semiconductor device 1 used in the preliminary study by the present inventor. For convenience, the bit lines 501 and the peripheral gates (gate electrodes) 502 are shown as transparent to facilitate understanding of the structure therebelow. Also, to facilitate understanding of the description, FIG. 1 shows an X-axis, a Y-axis orthogonal to the X-axis, and an X′ axis that forms a certain angle with respect to the X-axis.

A semiconductor substrate 100 is provided with a memory cell region 2 and a peripheral circuit region 3 adjacent to the memory cell region 2.

In the memory cell region 2, there are arranged parallelogram memory cell active regions 101 formed by dividing the semiconductor substrate 100, using element isolating regions 200, in the X′ direction, inclined from the X direction, and in the Y direction. Specifically, the memory cell active regions 101 are repetitively arranged, sandwiching the element isolating regions 200 in the X′ direction and Y direction. A plurality of memory cell active regions 101 aligned in the Y direction, and two buried word lines 300 extending in the Y direction and arranged so as to equally trisect the memory cell active regions 101, are arranged straddling the element isolating regions 200 between the memory cell active regions 101. In the three memory cell active regions 101 trisected by the two buried word lines 300, a bit line 501 extending in the X direction so as to connect a plurality of portions (intermediate portions) between two buried word lines 300 in the X direction, is arranged with the interposition of a first interlayer insulating film, to be described later. Specifically, the plurality of bit lines 501 are arranged in repeated fashion with a specified interval in the memory cell region 2. As will be described later, a first liner film 551 comprising a silicon nitride film and a second liner film 552 likewise comprising a silicon nitride film are arranged at the lateral surface of the bit line 501.

Next, rectangular peripheral circuit active regions 102 produced by dividing the semiconductor substrate 100 in the X direction and Y direction using element isolating regions 200 are arranged in the peripheral circuit region 3. Specifically, the peripheral circuit active regions 102 are arranged in repetitive fashion sandwiching the element isolating regions 200 in the X direction and Y direction. A plurality of peripheral circuit active regions 102 are aligned the Y direction, and peripheral gates 502 are arranged so as to equally bisect the peripheral circuit active regions 102, with a peripheral gate insulating film, to be described later, interposed therebetween, extending in the Y direction straddling the element separating regions 200 between the peripheral circuit active regions 102. At the lateral surface of the peripheral gates 502, there are arranged a first liner film 551 constituted by a silicon nitride film (first insulating film), a spacing film 560 constituted by a silicon oxide film (second insulating film), and a second liner film 552 constituted by a silicon nitride film (third insulating film). A peripheral LDD (Lightly Doped Drain) region 103 is provided in the peripheral circuit active region 102 by ion implantation, using the peripheral gates 502 and first liner film 551 as a mask. Also, a peripheral SD (Source/Drain) region 104 is provided in the peripheral circuit active region 102 by ion implantation, using the peripheral gates 502, first liner film 551 and spacing film 560 as a mask. The second liner film 552 is provided prior to the provision of a second interlayer insulating film, to be described later, comprising an SOD film.

Next, we refer to FIG. 2. FIG. 2 is a cross-sectional view along the line A-A in the memory cell region 2 of FIG. 1.

A plurality of memory cell active regions 101 are provided by partitioning the semiconductor substrate 100 using a plurality of element isolating regions 200. Bit lines 501 extending in the X direction shown in FIG. 1 are provided in repetitive fashion at a specified interval, with the interposition of a first interlayer insulating film 400, as described above, on the memory cell active regions 101 and element isolating regions 200. The detailed construction of the bit lines 501 is not shown. The first liner film 551 constituted by a silicon nitride film and the second liner film 552 likewise constituted by a silicon nitride film are arranged on the lateral surfaces of the bit lines 501. A second interlayer insulating film 600 comprising an SOD film is arranged on the entire surface of the semiconductor substrate 100, so as to bury the bit lines 501, first liner films 551, and second liner films 552. Capacitive contacts 700 are provided, passing through the second interlayer insulating film 600. The capacitive contacts 700 are connected with portions outside the two buried word lines 300, in the memory cell active regions 101 that are equally trisected by the two buried word lines 300 described above (FIG. 1), and that are not covered by the bit lines 501 and the first liner film 551 and the second liner film 552 on the lateral surfaces of the bit lines 501. A stopper film 780 and third interlayer insulating film 790 are arranged so as to cover the upper surface of the capacitive contacts 700 and second interlayer insulating films 600. A capacitor 800 comprising an upper electrode 803, a capacitive insulating film 802, and a lower electrode 801 connected with the upper surface of the capacitive contact 700 is provided, passing through the third interlayer insulating film 790 and stopper film 780. A fourth interlayer insulating film 900 and protective insulating film 930 are arranged on the capacitor 800.

Next, we shall refer to FIG. 3. FIG. 3 is a cross-sectional view along the line B-B in the peripheral circuit region 3 of FIG. 1.

A plurality of peripheral circuit active regions 102 are provided by partitioning the semiconductor substrate 100 by means of element isolating regions 200. Peripheral gates 502 are arranged, as described above, on the peripheral circuit active regions 102 and the element isolating regions 200, with the interposition of a peripheral gate insulating film 510. The detailed construction of the peripheral gates 502 is not shown. A first liner film 551 comprising a silicon nitride film, a spacing film 560 comprising a silicon oxide film and a second liner film 552 comprising a silicon nitride film are formed on the lateral surfaces of the peripheral gates 502.

A peripheral LDD (Lightly Doped Drain) region 103 is formed in the peripheral circuit active region 102 by ion implantation, using the peripheral gates 502 and first liner film 551 as a mask, and a peripheral S (Source)/D (Drain) region 104 is formed in the peripheral circuit active region 102 by ion implantation, using the peripheral gates 502, first liner film 551 and spacing film 560 as a mask.

After providing the second liner film 552 on the entire surface, the second interlayer insulating film 600 comprising an SOD film is provided so as to bury the peripheral gates 502, first liner film 551, spacing film 560, and second liner film 552. Reformation of the SOD film on the spacing film 560 comprising a silicon oxide film is insufficient, so it is necessary to provide this second liner film 552 comprising a silicon nitride film. The second liner film 552 is therefore also provided on the lateral walls of the bit lines positioned in the memory cell regions of FIG. 1 and FIG. 2.

Peripheral contacts 750 which are connected with the peripheral SD regions 104 are provided passing through the second interlayer insulating film 600. Peripheral wirings 760 are arranged on the second interlayer insulating film 600 so as to connect with the upper surface of the peripheral contacts 750. A stopper film 780, a third interlayer insulating film 790 and a fourth interlayer insulating film 900 are arranged so as to bury the peripheral wirings 760. Wiring contacts 910 which are connected with the peripheral wirings 760 are formed passing through the stopper film 780, the third interlayer insulating film 790 and the fourth interlayer insulating film 900. Wirings 920 are arranged on the fourth interlayer insulating film 900 so as to connect with the upper surface of the wiring contacts 910. Next, a protective insulating film 930 is arranged so as to bury the wirings 920.

According to the preliminary study described above which was conducted by the present inventor, a DRAM construction can be produced wherein a three-layer sidewall insulating film (551, 560, 552) is arranged on the lateral surfaces of the peripheral gates 502 and a two-layer sidewall insulating film (551, 552) is arranged on the lateral surfaces of the bit lines 501. However, there are drawbacks with this construction in dealing with miniaturization of the DRAM. These drawbacks will be described below with reference to FIG. 4. FIG. 4 is an enlargement of the area within the box C defined by the broken lines in FIG. 2.

The width W1 between adjacent bit lines 501 is reduced from left to right by an amount corresponding to the thickness t1 of the first liner film 551 and the thickness t2 of the second liner film 552, resulting in a width W2 for the capacitive contacts 700. If the first liner film 551 and second liner film 552 were eliminated, the width W2 would be increased, but this would result in short-circuiting of the capacitive contacts 700 and bit lines 501. The second liner film 552 is necessary as an under-layer film for formation of the SOD film constituting the second interlayer insulating film. Also, although it is possible to remove the spacing film 560 (FIG. 3), which is a silicon oxide film, by using the difference in selectivity with the first liner film 551, which is a silicon nitride film, the second liner film 552 is a silicon nitride film, like the first liner film 551, and therefore it cannot be removed after deposition. Consequently, there is a problem in that the width W1 between adjacent bit lines 501 is reduced from left to right by an amount corresponding to the thickness t1 of the first liner film 551 and the thickness t2 of the second liner film 552, resulting in the capacitive contact resistance increasing. For example, in the case of 6F² memory cells of 20 nm rule, the 8 nm-thick first liner film 551 and the 8 nm-thick second liner film 552 narrow the gap between adjacent bit lines, so the spacing width is narrowed to 53−(8+8)×2=21 nm.

### First Embodiment

Starting from the foregoing studies, the present inventor discovered the following, as a result of detailed observation of the various steps of bit line gate processing. By making the intervals between the plurality of bit lines 501 that are formed in the memory cell region 2 no more than twice the film thickness of the spacing film 560 that is formed as the sidewall of the peripheral gates 502, when the spacing film 560 comprising silicon oxide film is deposited, the space between adjacent bit lines 501 can be completely buried by the spacing film 560.

The idea of the present inventor was therefore that, instead of depositing the second liner film 552 after removal of the spacing film 560 of the memory cell region 2 by etching, it would be possible to ensure that the second liner film 552 was not deposited between adjacent bit lines 501 i.e. on the first liner film 551, by depositing the second liner film 552 in a state in which the space between the adjacent bit lines 501 was buried by the spacing film 560.

Based on the above idea, the method of manufacturing a semiconductor device according to the first embodiment of the present invention is described with reference to FIG. 5.

FIG. 5(a) is a block diagram showing in step order an outline of the method of manufacturing a semiconductor device according to the first embodiment of the present invention. FIG. 5(b) is a cross-sectional view showing the changes in cross-sectional shape of major portions of the semiconductor device in the step of FIG. 5(a), separately in the memory cell region (left hand side) and in the peripheral circuit region (right hand side). FIG. 6 is a cross-sectional view showing major portions of the semiconductor device according to the first embodiment, corresponding to FIG. 4.

First of all, by forming a plurality of element isolating regions 200 in the semiconductor substrate 100 using the STI (shallow trench isolation) technique, a plurality of memory cell active regions 101 are defined and formed in respect of the memory cell region 2 (see FIG. 1), and a plurality of peripheral circuit active regions 102 are defined and formed in respect of the peripheral circuit region 3 (see FIG. 1). After this, buried word lines (not shown) are formed and, in addition, bit lines 501 are formed in the memory cell active region 101, and peripheral gates 502 are formed in the peripheral circuit active region 102, respectively. The bit lines 501 are formed so as to have an interval of 53 nm. The detailed construction of the bit lines 501 and the peripheral gates 502 is not shown. An insulating film, such as for example a silicon nitride film, is deposited using the CVD (Chemical Vapor Deposition) method so as to cover the bit lines 501 and the peripheral gates 502, and a first liner film 551 (sidewall insulating film) is formed by etching back, leaving only portions that are in contact with the lateral surfaces of the bit lines 501 and the peripheral gates 502 (step PS1: formation of first liner film 551).

Next, the memory cell region 2 is protected by a resist 91 and ion implantation of impurities having opposite conductivity characteristics to those of the peripheral circuit active region 102 is performed, using the peripheral gates 502 and the first liner film 551 as a mask, to form the peripheral LDD region 103 (step PS2: formation of peripheral LDD region 103).

Next, using the CVD method, with for example TEOS (Tetraethyl Orthosilicate) as the material, a silicon oxide film of thickness 30 nm is deposited over the entire surface of the semiconductor substrate 100, including the surfaces (upper surfaces) of the bit lines 501 and peripheral gates 502, and the lateral surfaces covered by the first liner film 551. After this, a spacing film 560 is formed only in the portions contacting the lateral surfaces of the bit lines 501 and the peripheral gates 502 covered by the first liner film 551, using an etching back method based on dry etching. Now, since the interval between the bit lines 501 is specified as 53 nm, when the spacing films 560 of thickness 30 nm are formed, adjacent spacing films 560 are in contact in the space between adjacent bit lines 501 and the region between adjacent bit lines 501 is thus completely buried by the first liner films 551 and spacing films 560 (step PS3: formation of spacing films 560). It should be noted that, in the intermediate-stage figure of FIG. 5(b), the spacing of the bit lines 501 is shown as more than twice the thickness of the spacing films 560 but this is merely to facilitate comprehension. In fact, the spacing of the bit lines 501 is no more than twice the film thickness of the spacing films 560.

Next, the memory cell region 2 is protected by a resist 91, and, using the peripheral gates 502, the first liner film 551 and the spacing film 560 as a mask, the peripheral SD region 104 of higher concentration than the peripheral LDD region 103 is formed by ion implantation of impurity of opposite conductivity characteristics to those of the peripheral circuit active region 102. If a p-type substrate is employed as the semiconductor substrate 100, the peripheral LDD region 103 and the peripheral SD region 104 may be formed by n-type impurity such as phosphorus or arsenic. The impurity concentration of the peripheral LDD region 103 is in the range of 1E18 to 1E19 (atoms/cm³), and the impurity concentration of the peripheral SD region 104 is in the range 1E20 to 1E21 (atoms/cm³) (step PS4: formation of peripheral SD region 104).

Next, using the CVD method, an insulating film, for example a silicon nitride film, is deposited over the entire surface of the semiconductor substrate 100, including the surfaces (upper surfaces) of the bit lines 501 and peripheral gates 502, and the lateral surfaces covered by the first liner film 551 and the spacing film 560. Next, by etching back, the second liner film (sidewall insulating film) 552 is formed only in the portions in contact with the lateral surfaces of the peripheral gates 502 covered by the first liner film 551 and the spacing film 560 (step PS5: formation of second liner film 552).

Next, an SOD film is formed on the entire surface, using a spin-coating method. For the SOD film, polysilane, dissolved in a solvent, is employed. After forming an SOD film over the entire surface on the semiconductor substrate 100 by the spin-coating method, a first heat treatment step is performed for 30 minutes in a steam atmosphere at 350° C., 400 Torr. After this, a second heat treatment step is performed for 30 minutes in a steam atmosphere at 500° C. and normal pressure. In addition, a third heat treatment step is performed for 30 minutes at 600° C., in a nitrogen atmosphere at normal pressure. As a result, the polysilane is oxidation-reformed and converted to a silicon oxide film. After this, the surface (upper surface) of the SOD film (silicon oxide film) is polished flat to form the second interlayer insulating film 600 by a CMP (Chemical Mechanical Polishing) method. Using the CMP method, the upper surface of the peripheral gates 502 and the bit lines 501 may be leveled (made flush) (step PS6: formation of second interlayer insulating film 600).

With the first embodiment, as shown in FIG. 6, in the memory cell region 2 (see FIG. 1), only the first liner film 551 and the spacing film 560 are present between the bit lines 501. Specifically no second liner film 552 as shown in FIG. 4 is present. Consequently, when the capacitive contact holes are formed by selective etching of the spacing film 560 by the dry etching method, the width W2 of the capacitive contact holes (i.e. the width W2 of the capacitive contact plugs) can be made wider by an amount of twice the thickness t2 (see FIG. 4) of the second liner film 552. Specifically, taking as an example a 20 nm rule 6F² memory cell, if the width W3 between bit lines is 53 nm, the thickness t1 of the first liner film 551 is 8 nm, and the thickness t2 of the second liner film 552 is 8 nm, in the example of FIG. 4, the spacing between the bit lines 501 is narrowed by the first liner film 551 and second liner film 552, and therefore the capacitive contact width W2 is 53−(8+8)×2=21 nm. In contrast, with the first embodiment shown in FIG. 6, since the first liner film 551 is only 8 nm thick, the capacitive contact width W2 can be expanded to 53−(8)×2=37 nm.

A semiconductor device 1 as shown in FIG. 1 is subsequently manufactured using the same capacitor and wiring formation steps as in the previous technology.

### Second Embodiment

Next, a method of manufacturing a semiconductor device according to a second embodiment of the present invention is described with reference to FIG. 7.

When burying holes or grooves of large aspect ratio, gaps may be created in the middle of the holes or grooves of the spacing film 560 made of TEOS. If gaps are produced in the middle of the spacing film 560, the material of the capacitive contacts may penetrate into these during subsequent formation of the capacitive contacts, resulting in short-circuiting of adjacent capacitive contacts. A second embodiment of the present invention was accordingly devised.

FIG. 7(a) is a block diagram showing in step order an outline of the method of manufacturing a semiconductor device according to the second embodiment of the present invention. FIG. 7(b) is a cross-sectional view showing the changes in the cross-sectional shape of major portions of the semiconductor device in the steps of FIG. 7(a), separately in the memory cell region (left hand side) and the peripheral circuit region (right hand side).

First of all, the steps (steps PS1 to PS5) as far as formation of the second liner film 552 are performed in the same way as in the first embodiment. At this stage, the spaces between adjacent bit lines 501 in the memory cell region are buried by the spacing film 560, comprising a silicon oxide film, formed by the CVD method. In this second embodiment, the peripheral circuit region 3 is then protected by a resist 91 and the spacing film 560 comprising a silicon oxide film formed in the memory cell region 2 is removed by a wet etching method: once this has been done, this makes possible selective etching of the silicon nitride film. For wet etching, a fluoric acid (HF)-containing solution is employed (step PS5′: wet etching of spacing film 560 of memory cell region 2).

Next, an SOD film is formed by the same method as the method described in the first embodiment, and, in addition, the SOD film is converted to a silicon oxide film by oxide reformation. After this, the SOD film (silicon oxide film) is polished flat by the CMP method, to form the second interlayer insulating film 600. The space between adjacent bit lines 501 in the memory cell region is thereby buried (step PS6: formation of second interlayer insulating film 600) by a silicon oxide film produced by oxide reformation of the SOD film formed by the spin-coating method.

A semiconductor device 1 as shown in FIG. 1 is subsequently manufactured using the same capacitor and wiring forming steps as in the previous technology.

With the second embodiment, just as in the case of the first embodiment, the width W2 of the capacitive contact plugs can be expanded by an amount of twice the thickness t2 of the second liner film 552 (FIG. 4). In addition, with the second embodiment, the space between adjacent bit lines 501 is formed by a silicon oxide film obtained by oxide reformation of an SOD film formed by a spin-coating method, instead of a silicon oxide film formed by the CVD method. A silicon oxide film formed by a CVD method is conformally formed, and therefore in the grooves formed by adjacent bit lines 501, seams may be produced in portions where silicon oxide films deposited from both lateral surfaces of the grooves meet. If seams are present, voids (openings) are formed for example by washing after capacitive contact hole formation. Such voids are a cause of short-circuiting of adjacent capacitive contact plugs. However, with the second embodiment, formation of seams can be completely avoided, since the silicon oxide film is formed using an SOD film that was formed by a spin-coating method, which involves fluidity. As a result, the risk of short-circuiting capacitive contact plugs can be avoided.

While the present invention has been described with reference to a plurality of embodiments, the present invention is not restricted to the embodiments described above. The layout and details of the present invention could be altered in various ways, which will be understood by person skilled in the art, within the spirit or scope of the present invention as set out in the claims.

This application claims priority based on Japanese patent application 2012-251378, which was filed on Nov. 15, 2012, and the entire disclosure thereof is incorporated herein.

### EXPLANATION OF THE REFERENCE SYMBOLS

1 DRAM semiconductor device
2 Memory cell region
3 Peripheral circuit region
91 Resist
100 Semiconductor substrate
101 Memory cell active region
102 Peripheral circuit active region
103 Peripheral LDD region
104 Peripheral SD region
200 Element isolating region
300 Buried word line
400 First interlayer insulating film
501 Bit line
502 Peripheral gate
510 Peripheral gate insulating film
551 First liner film
552 Second liner film
560 Spacing film
600 Second interlayer insulating film
700 Capacitive contact
750 Peripheral contact
760 Peripheral wiring
780 Stopper film
790 Third interlayer insulating film
800 Capacitor
801 Lower electrode
802 Capacitive insulating film
803 Upper electrode
900 Fourth interlayer insulating film
910 Wiring contact
920 Wiring
930 Protective insulating film

1. A semiconductor device comprising:
a memory cell region;
a peripheral circuit region on a semiconductor substrate;
bit lines arranged on said semiconductor substrate in said memory cell region;
gate electrodes of transistors for peripheral circuits arranged on said semiconductor substrate in said peripheral circuit region;
a plurality of sidewall insulating films on the lateral surfaces of said gate electrodes and
a single-layer sidewall insulating film arranged on the lateral surfaces of said bit lines.

2. A method of manufacturing a DRAM semiconductor device, the method comprising:
simultaneously forming a plurality of bit lines in a memory cell region on a semiconductor substrate and gate electrodes of transistors for peripheral circuits in a peripheral circuit region;
forming, by etching back, a first liner film using a first insulating film only in a portion contacting the lateral surfaces of said bit lines and the lateral surfaces of said gate electrodes, after deposition of said first insulating film so as to cover said bit lines and said gate electrodes; and
forming, by etching back, a spacing film using a second insulating film only in a portion contacting the lateral surfaces of said bit lines and said gate electrodes covered by said first liner film, after deposition, to a prescribed thickness, of said second insulating film, which is made of a different material from said first insulating film, in a region including the surfaces of said bit lines and said gate electrodes and the lateral surfaces covered by said first liner film;
wherein the interval between said plurality of bit lines is set so that, when said spacing film is formed to said prescribed thickness, the space between adjacent bit lines is buried by said first liner film and said spacing film formed thereon; and
after the step of forming said spacing film, deposition of a third insulating film made of the same material as said first insulating film in a region including the surfaces of said bit lines and said gate electrodes and the lateral surfaces covered by said first liner film and said spacing film, and then forming, by etching back, a second liner film using said third insulating film, only in a portion contacting the lateral surfaces of said gate electrodes covered by said spacing film and said first liner film.

3. The method of claim 2, wherein the interval between said bit lines is no more than twice said prescribed thickness of said spacing film.

4. The method of claim 2, comprising, after forming said second liner film, forming an SOD film on the entire surface, then performing heat treatment to convert this to an oxide film and then forming an interlayer insulating film by polishing said oxide film flat.

5. The method of claim 2, comprising:
after forming said second liner film, removing said spacing film formed on said memory cell region side, by means of selective wet etching while protecting said peripheral circuit region side with a resist; and
forming an interlayer insulating film by forming an SOD film over the entire surface by a spin-coating method, then converting this to an oxide film by heat treatment, then polishing said oxide film flat;
wherein the space between said bit lines in said memory cell region is buried by said oxide film obtained by conversion of said SOD film.

6. The method of claim 2, wherein said spacing film is formed by forming a silicon oxide film by a CVD method using TEOS as the starting material.
